(19) United States
(12) Patent Application Publication
(10) Pub. No.: US 2004/0175924 A1
(43) Pub. Date: Sep. 9, 2004

(54) Semiconductor device having resistor and method of fabricating the same

(75) Inventors: Eun-Young Choi, Kyungki-do (KR); Sung-Nam Chang, Seoul (KR); Won-Hong Lee, Kyungki-do (KR); Kwang-Shik Shin, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 10/792,439

(22) Filed: Mar. 2, 2004

(30) Foreign Application Priority Data
Mar. 7, 2003 (KR) 2003-14385

(51) Int. Cl. H01L 31/20

(52) U.S. Cl. 438/622

(57) ABSTRACT

A method according to some embodiments of the invention includes sequentially forming first and second conductive layers, patterning the second conductive layer to form second conductive patterns, and forming a mask pattern connecting the second conductive patterns. Using the mask pattern and the second conductive patterns as an etching mask, the first conductive layer is etched to form a first conductive pattern electrically connecting the second conductive patterns. Before the second conductive layer is formed, a gate interlayer insulating layer including at least two openings exposing a top surface of the first conductive layer may be formed. The second conductive patterns are in contact with top surfaces of the first conductive pattern. During formation of the second conductive patterns, a dummy pattern may be formed on the gate interlayer insulating layer and spaced apart from the second conductive patterns.

### CROSS REFERENCE TO RELATED APPLICATIONS

This application claims priority from Korean Patent Application 2003-14385, filed on Mar. 7, 2003, the contents of which are hereby incorporated by reference in their entirety.

### BACKGROUND OF THE INVENTION

1. Technical Field of the Invention

This disclosure relates to semiconductor devices, and more particularly to semiconductor devices having resistors and methods for fabricating the same.

2. Description of the Related Art

Most electric appliances, such as televisions, telephones, radios, and computers, employ semiconductor devices, for example, an integrated circuit and a memory chip. The semiconductor devices include various microelectronic devices such as transistors, capacitors, diodes, and resistors.

Materials used to form the semiconductor devices may be classified as either conductive materials, insulating materials, or semiconductor materials according to resistances. The conductive materials used in the semiconductor devices include aluminum, tungsten, copper, titanium, etc., and have low resistivity (several micro-angstrom-centimeters). Thus, most of the conductive materials are used as interconnections that electrically connect the microelectronic devices. The insulating materials include silicon oxide, silicon nitride, etc. and have high resistivity. Thus, the insulating materials are used to insulate the conductive materials.

The resistor is a simple electrical element but plays an important role in a circuit operation. The resistor may have various resistances according to uses of the semiconductor devices. Especially in flash memory (a highly integrated device having complex functions) there is a need for various resistors having different resistances.

It is easy to fabricate low-resistance resistors using conductive materials having low resistivity. However, in order to fabricate high-resistance resistors (hundreds of KΩ) from the same material, a much longer resistor is required. This increases the resistor area and cause problems in integration density. Alternatively, resistors may be formed of conductive material having sufficiently high resistivity. However, this approach increases fabrication cost because now another material is needed in addition to the materials that are already used in the fabricating process.

Accordingly, most semiconductor products employ polysilicon (used to fabricate gate electrodes) as the resistor. The polysilicon has about 1000 μΩcm resistivity, which is higher than that of the metallic materials, but lower than that of the insulating materials. Therefore, when the resistors are formed of polysilicon, over-lengthening of the resistors can be prevented. In addition, the resistor can be formed without additional materials because the polysilicon is widely used in the fabricating process of the semiconductor devices.

FIG. 1 is a cross-sectional diagram illustrating a method for fabricating a flash memory resistor according to the prior art.

Referring to FIG. 1, a field isolation layer 20 is formed in a predetermined region of a semiconductor substrate 10. Then, a first conductive pattern 30, a gate interlayer insulating layer 40, and a second conductive pattern 50, which are sequentially stacked, are formed on the field isolation layer 20.

The first and second conductive patterns 30 and 50 include polysilicon layers. However, if the second conductive pattern 50 is formed only of polysilicon having high resistivity, the resistance of a control gate electrode increases to the point where it is capable of causing delay in word lines of the flash memory. To prevent the delay, the second conductive pattern 50 is formed with a sequential stack structure of polysilicon 52 and tungsten silicide 54 that has low resistivity. Consequently, the resistance of the second conductive pattern 50 is too low to fabricate a high resistance resistor.

The first conductive pattern 30 consisting of only polysilicon may be used as the high resistance resistor used in the flash memory. The second conductive pattern 50 is shorter than the first conductive pattern 30 and disposed on the center of the first conductive pattern. Thus, the second conductive pattern 50 exposes both edges of the first conductive pattern 30. Generally, the gate interlayer insulating layer 40 is formed with a sequential stack structure of oxide-nitride-oxide (ONO).

An interlayer insulating layer 70 is formed on the semiconductor substrate and the second conductive pattern 50. Then, the interlayer insulating layer 70 is patterned to form openings 75 exposing a top surface of the first conductive pattern 30. The openings 75 are formed at both ends of the first conductive pattern 30. Interconnections 80 are formed to fill the opening 75 and be in contact with the first conductive pattern 30. The first conductive pattern 30 connected to the interconnections 80 is used as a resistor in the flash memory.

As semiconductor devices become increasingly integrated, a width of the gate pattern also decreases. As a result, a surface resistance of the gate electrode increases. To compensate for the increase of the surface resistance, the gate pattern becomes higher but this causes various difficulties in a pattering process or a process of filling with the interlayer insulating layer 70 for the high gate pattern. Accordingly, there is a need to reduce a height of the floating gate of the flash memory to solve those problems. As a result, the floating gate is as high as the first conductive pattern 30.

The anisotropic etch process for forming the opening 75 is performed by an over-etch method in order to prevent connection defects between the interconnections 80 and the first conductive pattern 30. Even though the etch process uses an etch recipe having etch selectivity with respect to the first conductive pattern 30, the first conductive pattern 30 and the floating gate are shortened in height, such that the contact resistance between the interconnections 80 and the first conductive pattern 30 may increase.

In particular, because the etch process for forming the opening 75 utilizes the process for forming contact plugs on source/drain of a cell transistor, the etch process is performed under a condition of recessing the substrate to a specific thickness. Therefore, the opening 75 penetrates the thin first conductive pattern 30 to be capable of exposing the field isolation layer 20. The contact resistance may dramatically increase depending on a variation of the contact area. This increase of the contact resistance makes the resistance irregular.

Embodiments of the invention address these and other disadvantages of the prior art.

### SUMMARY OF THE INVENTION

According to some embodiments of the invention, a semiconductor device with resistors that have a uniform resistance may be formed during the process of forming a memory cell gate pattern. Therefore, good-quality resistors may be fabricated without additional expensive processing steps.

### BRIEF DESCRIPTION OF THE DRAWINGS

FIG. 1 is a cross-sectional diagram illustrating a conventional method for fabricating a flash memory resistor.

FIGS. 2A-5A and 2B-5B are top plan diagrams and cross-sectional diagrams, respectively, illustrating a method for forming a resistor according to some embodiments of the invention.

FIGS. 6A-8A and 6B-8B are top plan diagrams and cross-sectional diagrams, respectively, illustrating a method for forming a resistor according to some other embodiments of the invention.

FIG. 9 is a cross-sectional diagram illustrating a specific region of a NAND-type flash memory formed according to some embodiments of the invention.

FIG. 10 is a perspective diagram illustrating a resistor according to some embodiments of the invention.

FIG. 11 is a perspective diagram illustrating a resistor according to some other embodiments of the invention.

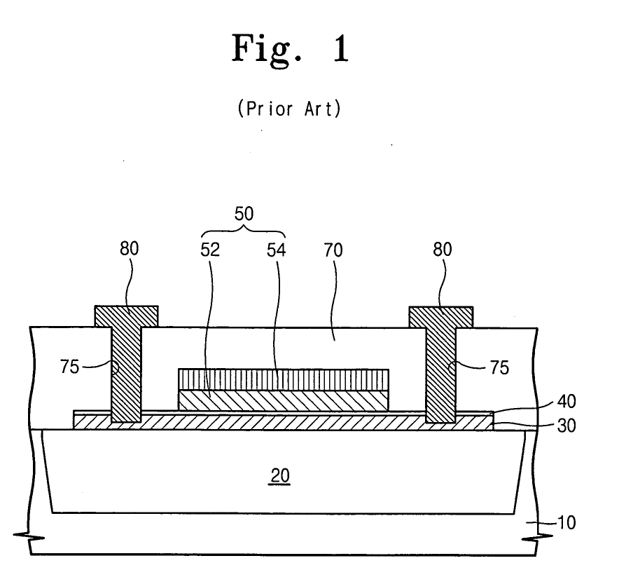

### DETAILED DESCRIPTION OF THE INVENTION

The invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present.

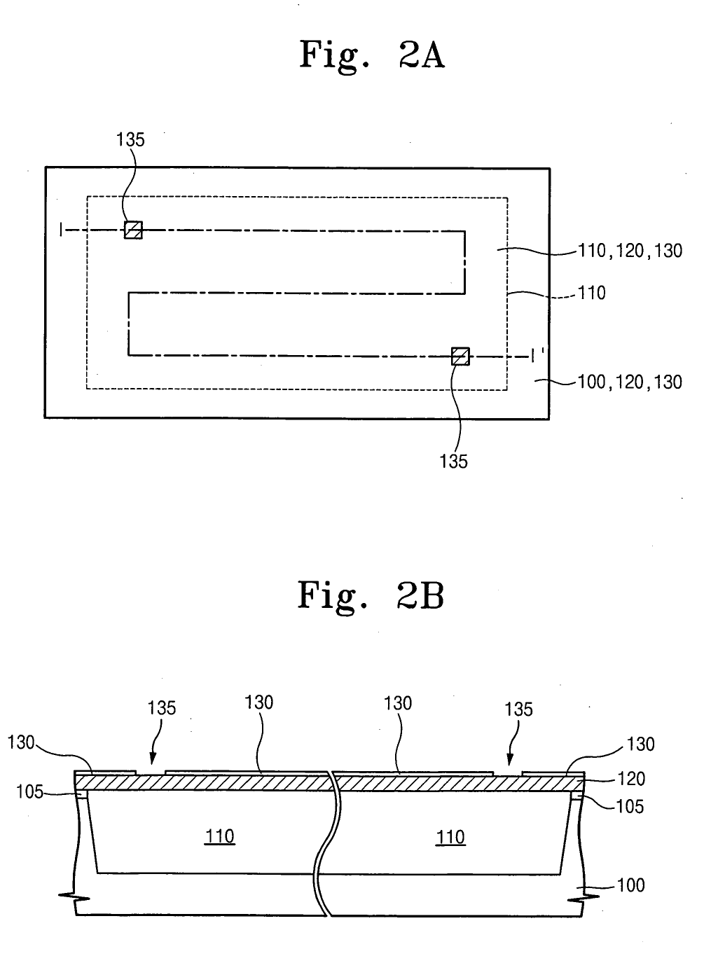

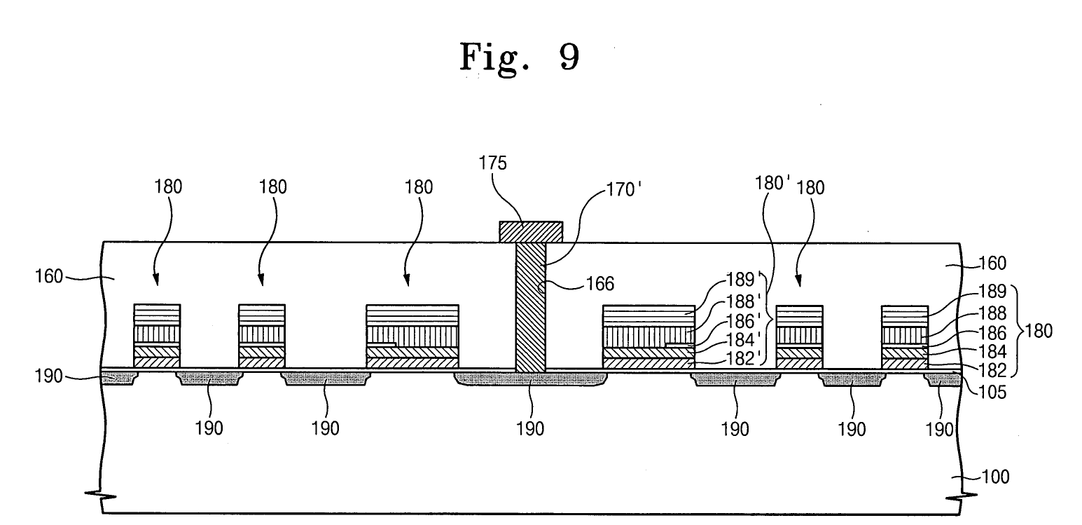

FIGS. 2A-5A and 2B-5B are top plan diagrams and cross-sectional diagrams, respectively, illustrating a method for forming a resistor according to some embodiments of the invention. FIGS. 2B-5B are cross sectional diagrams taken along the dotted line I-I′ of FIGS. 2A-5A, respectively. Meanwhile, FIG. 9 is portion of cell array region of a NAND-type flash memory formed in the manner of the exemplary embodiment of the invention.

Referring to FIGS. 2A and 2B, a field isolation layer 110 is formed in a predetermined region of a semiconductor substrate 100. The field isolation layer 110 may be formed using trench technologies. Trench technologies include forming a trench mask pattern covering the active region and etching the semiconductor substrate 100 using the trench mask pattern as an etch mask. The trench mask pattern may be formed of silicon oxide and polysilicon.

According to an exemplary embodiment of the invention, the field isolation layer 110 defines a cell array region and a peripheral circuit region of a flash memory. A resistor is disposed at the peripheral region where the resistor will be formed. FIG. 9 is a cross-sectional diagram showing a portion of the cell array region of the flash memory. FIGS. 2A and 2B are top plan diagrams and cross-sectional diagrams, respectively, showing the resistor region.

A gate oxide layer 105 and a first conductive layer 120 are sequentially formed on the semiconductor substrate with the field isolation layer 110. The gate oxide layer 105 may be formed with thermal oxidation on a portion of a top surface of the semiconductor substrate, and may be a silicon oxide layer used as the trench mask pattern. As illustrated in FIG. 9, the polysilicon layer 182 used as the trench mask pattern may compose a floating gate of the flash memory.

The first conductive layer 120 may be formed of polysilicon at 100-400 Å thickness. A gate interlayer insulating layer 130 is formed to cover a surface of the first conductive layer 120. The gate interlayer insulating layer 130 may be formed of sequentially stacked silicon oxide-silicon nitride-silicon oxide (ONO) layers. The gate interlayer insulating layer 130 is patterned to form a plurality of openings 135 exposing a top surface of the first conductive layer 120. The openings 135 may be formed at the cell array region and the resistor device region. The openings 135 of the cell array region expose the first conductive layer 120 at the position a source selection gate or a ground selection gate will be formed. In addition, the openings 135 of the resistor region expose the first conductive layer 120 at the position where a second conductive pattern will be defined in a subsequent process.

According to some embodiments of the present invention, a first conductive layer 120 may be patterned at the cell array region before forming the gate interlayer insulating layer 130. Therefore, the patterned first conductive layer covers the active region and is parallel to the field isolation layer 110. Patterning of the first conductive layer 120 is performed so as not to etch the first conductive layer 120 at the resistor region.

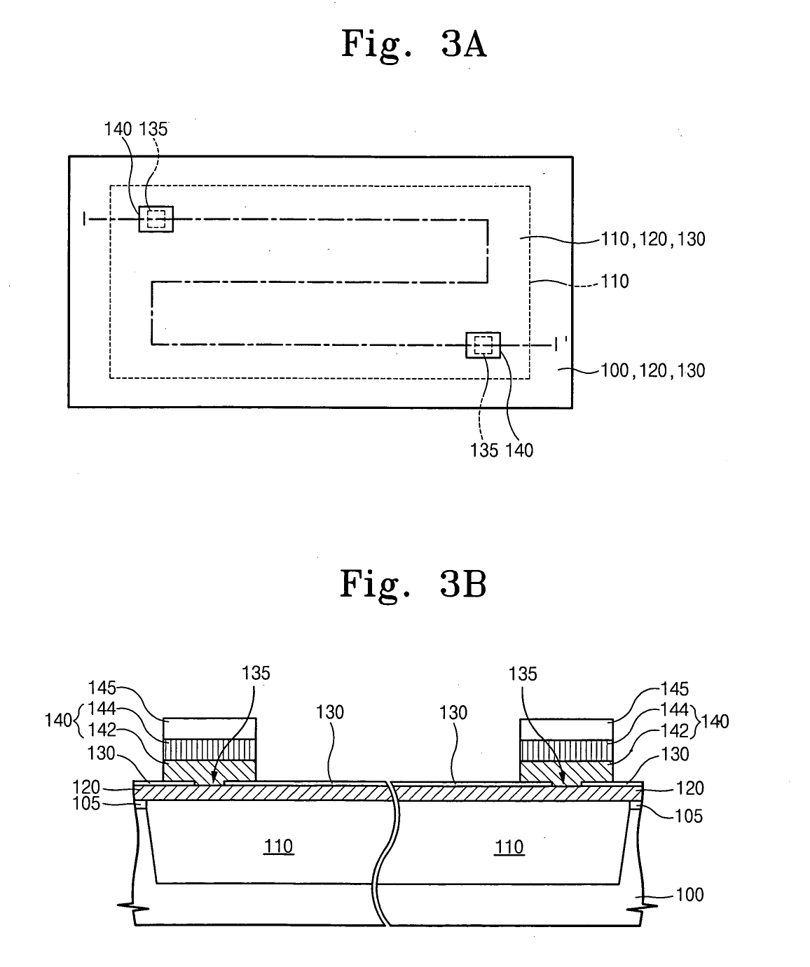

Referring to FIGS. 3A and 3B, a second conductive layer is formed on the semiconductor substrate with the openings 135. The second conductive layer is formed of conductive material having etch selectivity with respect to the gate interlayer insulating layer 130. For example, the second conductive layer may be formed of at least one selected from polysilicon, tungsten, tungsten silicide and cobalt silicide.

According to an exemplary embodiment of the invention, the second conductive layer includes a bottom second conductive layer and a top second conductive layer. The bottom second conductive layer is a polysilicon layer and the top second conductive layer is a tungsten silicide layer.

The second conductive layer is patterned until a top surface of the gate interlayer insulating layer 130 is exposed, therefore forming second conductive pattern 140 disposed on the openings 135 in the resistor region. Therefore, the second conductive patterns 140 are directly in contact with the first conductive layer 120 through the openings.

The step of patterning the second conductive layer may be performed by an anisotropic etching process having etch selectivity with respect to the gate interlayer insulating layer 130. Therefore, the first conductive layer 120 may not be etched under the gate interlayer insulating layer 130. Meanwhile, in order to use the second conductive pattern 140 as an etch mask, a capping layer may be additionally formed on the second conductive layer before the second conductive layer is patterned. In the illustrated embodiments, a capping pattern 145 is formed on the second conductive pattern 140.

According to an exemplary embodiment of the invention, forming the second conductive patterns 140 may be accomplished at the same time the flash memory control gate electrodes are formed, using the same process (refer to 188 and 189 in FIG. 9). The control gate electrodes 188 and 189 are formed in the cell array region and the second conductive patterns 140 are formed in the resistor region.

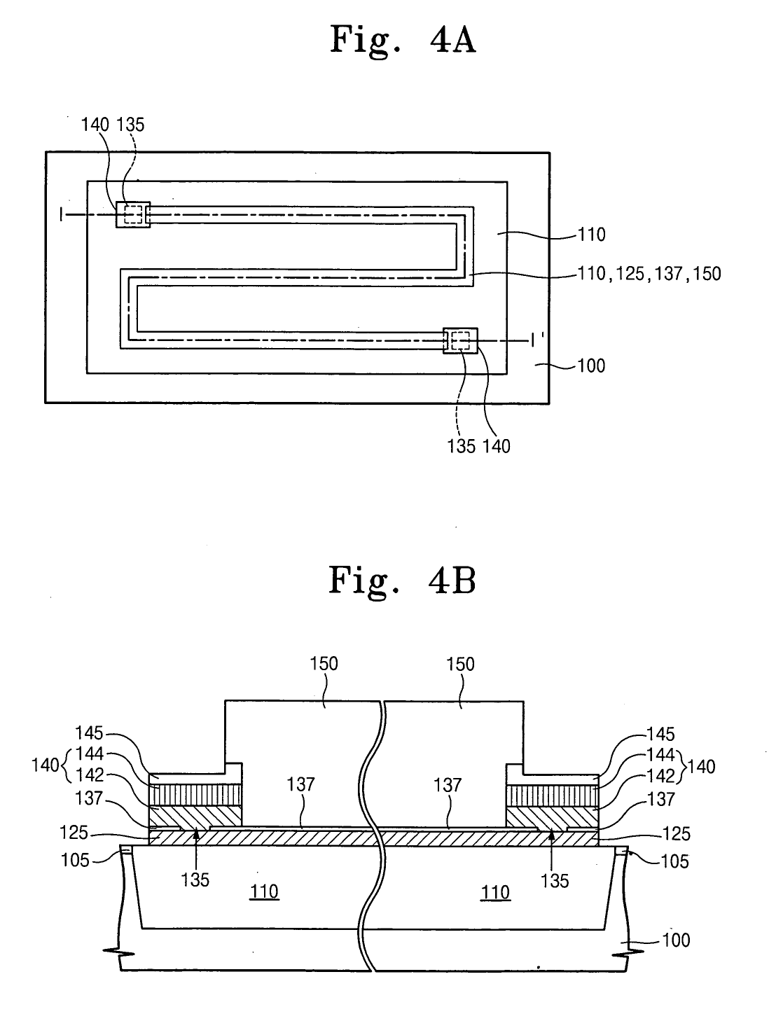

Referring to FIGS. 4A and 4B, a mask pattern 150 is formed on a semiconductor substrate with the second conductive patterns 140. The mask pattern 150 may be a photoresist layer formed by a conventional photolithography process. The mask pattern 150 is used as an etch mask for defining a resistor pattern in accordance with embodiments of the invention. It is desirable to form the mask pattern 150 to overlap the second conductive patterns 140 and/or the capping pattern 145.

Using the mask pattern 150 and the capping pattern 145 as an etch mask, the gate interlayer insulating layer 130 and the first conductive layer 120 are successively etched. Therefore, a first conductive pattern 125 that will be connected to the second conductive patterns 140 through the openings 135 is formed under mask pattern 150. A gate interlayer insulating pattern 137 having the openings 135 is interposed between the first conductive pattern 125 and the second conductive pattern 140.

Meanwhile, the method of fabricating a flash memory illustrated in FIG. 9 may include the forming a photoresist pattern that covers the peripheral circuit region but exposes the cell array region. The photoresist pattern forms a cell-opening mask that is used as an etch mask for forming a gate pattern with stacked structure at the cell array region. The photoresist pattern also protects the peripheral region where a floating gate electrode is not required. According to an exemplary embodiment of the invention, the cell-opening mask is used as the mask pattern 150. Therefore, the first conductive pattern 125 may be fabricated without additional processes.

In the embodiment using the cell-opening mask as a mask pattern 150, material layers of the exposed cell array region are etched while the first conductive pattern 125 is formed. The capping pattern 145 may be used as an etch mask while the first conductive pattern 125 is formed at the resistor region. As a result, the cell gate patterns 180 and the selection gate patterns 180′ are formed on the semiconductor substrate with the gate oxide layer 105 at the cell array region as illustrated in FIG. 9.

The cell gate patterns 180 include a bottom floating gate 182, a top floating gate 184, a gate interlayer insulating layer pattern 186, a bottom control gate 188, and a top control gate 189 that are sequentially stacked. In addition, the selection gate patterns 180′ include a first selection gate 182′, a second bottom selection gate 184′, a gate interlayer insulating pattern 186′, a first top selection gate 188′, and a second top selection gate 189′ that are sequentially stacked. The bottom floating gate 182 and the first bottom selection gate 182′ are formed of identical material and used as the trench mask pattern.

The top floating gate 184, the second lower selection gate 184′, and the first conductive pattern 125 originate from the first conductive layer 120 and formed of identical material. Similarly, the control gates 188 and 189 and the top selection gates 188′ and 189′ originate from the second conductive layer. The etch process for forming the opening 135 etches the gate interlayer insulating layer 130 at the region where the selection gate patterns 180′ are formed. Therefore, a gate interlayer insulating pattern 186′ of the selection gate pattern 180′ covers only edges of the second bottom selection gate 184′, such that the second bottom selection gate 184′ is directly in contact with the first top selection gate 188′.

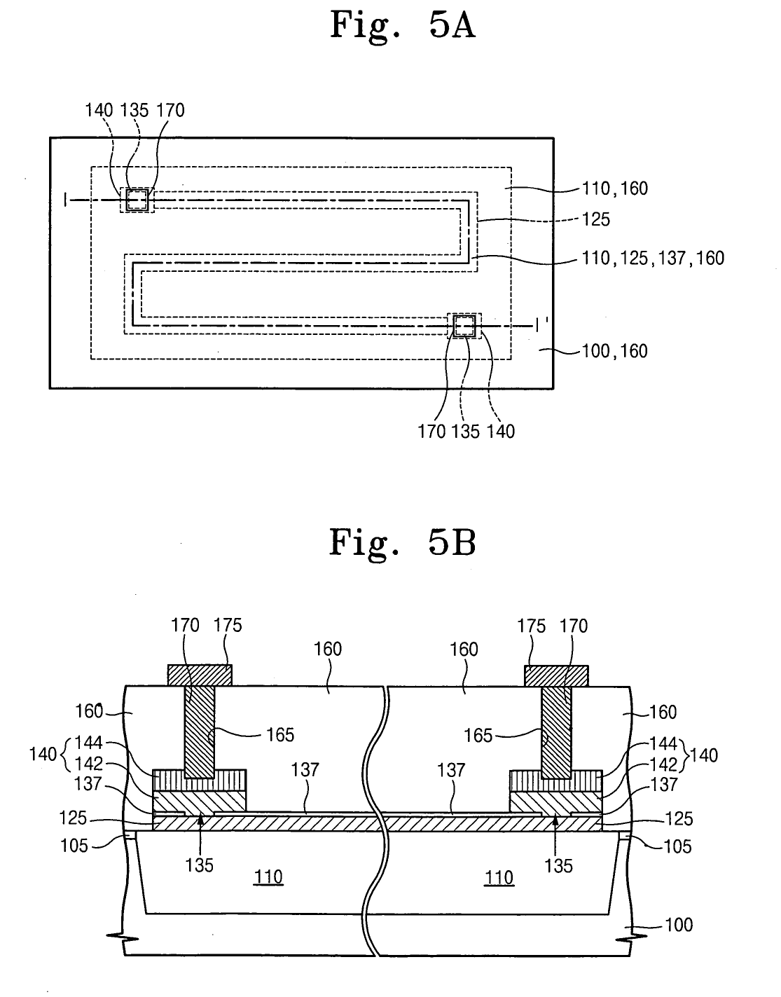

Referring to FIGS. 5A and 5B, the mask pattern 150 is removed. Therefore, the gate interlayer insulating pattern 137 covering the first conductive pattern 125 is exposed at the resistor region. An interlayer insulating layer 160 is formed on an entire surface of the semiconductor substrate without the mask pattern 150 and then patterned to form holes 165 exposing top surfaces of the second conductive patterns 140. Plugs 170 are formed to fill the holes 165 and an interconnection 175 is formed on the interlayer insulating layer to connect the plug 170.

Before forming the interlayer insulating layer 160, an ion implantation process may be used to form impurity regions 190 that are used as source/drain regions of a transistor. The impurity region 190 may be formed using the cell gate pattern 180 and the selection gate pattern 180′ as an ion implantation mask. In order to form the impurity region 190 with LDD structure, spacers (not shown) may be formed on sidewalls of the gate patterns 180 and 180′. The process of forming the holes 165 is performed by an anisotropic etching and may use an etch recipe having etch selectivity with respect to the second conductive pattern 140. While the holes 165 are formed, a contact hole 166 is formed at the cell array region to expose the impurity region 190. In addition, while the plug 170 is formed, a contact plug 170′ is formed to connect the impurity region 190.

According to embodiments of the invention, the plug 170 is not in contact with the first conductive pattern 125 but with the second conductive pattern 140. Therefore, a drastic increase in the contact resistance may be prevented. In addition, only a small portion of the first conductive pattern 125 is covered by the second conductive patterns 140 at both edges of the first conductive pattern. Therefore, a trim process is available in order to control the resistance. The trim process cuts a portion of the resistor region by laser.

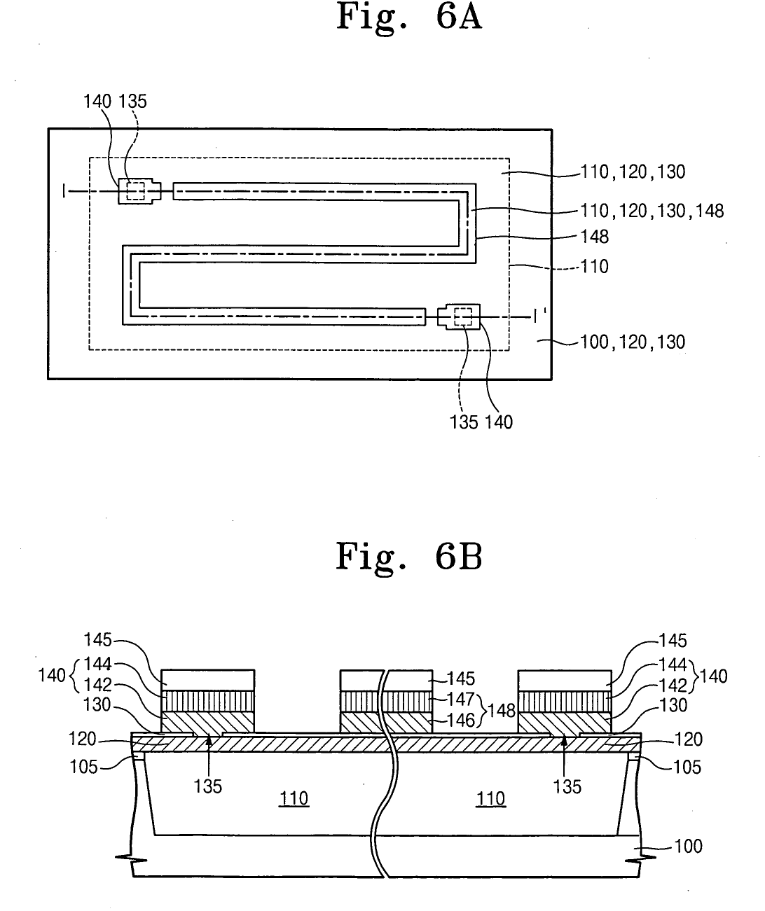

FIGS. 6A-8A and FIGS. 6B-8B are top plan diagrams and cross sectional diagrams, respectively, showing a method for fabricating a semiconductor device in accordance with some other embodiments of the invention. FIGS. 6B-8B are cross sectional diagrams taken along the dotted line I-I′ of FIGS. 6A-8A. The embodiments illustrated in FIGS. 6-8 share some common characteristics with the embodiments illustrated in FIGS. 2-5 and to avoid unnecessary repetitiveness a duplicative explanation will be avoided. In particular, the fabricating steps illustrated in FIGS. 2A and 2B are the same for the embodiments illustrated in FIGS. 6-8 and are therefore omitted.

Referring to FIGS. 6A and 6B, a dummy pattern 148 is formed on the region where the first conductive pattern 125 will be formed. The dummy pattern 148 and the second conductive pattern 140 are formed during the same process. The dummy pattern 148 may be a mask defining a pattern used as a resistor, and unlike the second conductive pattern 140, may be electrically insulated from the first conductive layer 120. Therefore, the dummy pattern 148 is spaced apart from the second conductive pattern 140, and the gate interlayer insulating layer 130 is interposed between the first conductive layer 120 and the dummy pattern 148.

The dummy pattern 148 includes a bottom dummy pattern 146 and a top dummy pattern 147 that are sequentially stacked on the gate interlayer insulating layer 130. The top and bottom dummy patterns 146 and 147 are formed of the same material as the top and bottom second conductive patterns 142 and 144, respectively, which are separated as a result of the patterning of the second conductive layer.

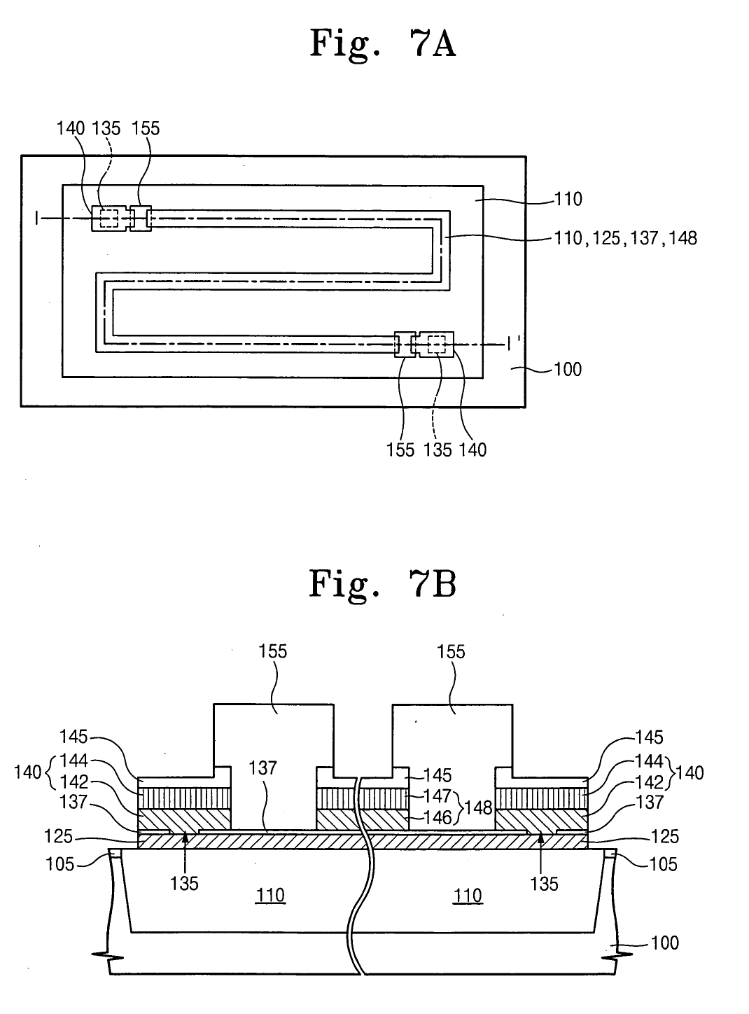

Referring to FIGS. 7A and 7B, a mask pattern 155 may be formed to cover the gate interlayer insulating layer 130 between the second conductive patterns 140 and the dummy pattern 148. Using the mask pattern 155, the dummy pattern 148, and the second conductive patterns 140 as an etch mask, the gate interlayer insulating layer 130 and the first conductive layer 120 are anisotropically etched.

Therefore, a first conductive pattern 125 and a gate interlayer insulating pattern 137 are stacked, in that order, on the field isolation layer 110. The gate interlayer insulating pattern 137 includes openings 135 formed under the second conductive patterns 140. Through the openings 135, the second and first conductive patterns 140 and 125 are in direct contact with each other. However, the first conductive pattern 125 and the dummy pattern 148 are insulated by the gate insulating pattern 137 interposed between.

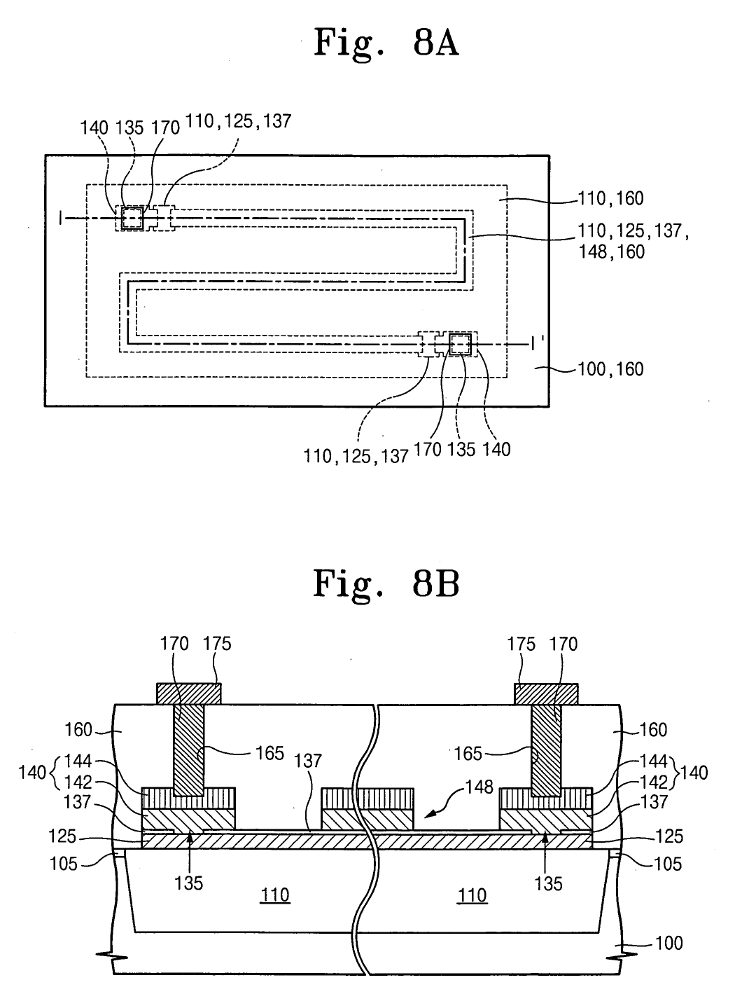

Referring to FIGS. 8A and 8B, the mask pattern 155 is removed. An interlayer insulating layer 160, holes 165, a plug 170 and an interconnection 175 are formed in the same way as the method illustrated in FIGS. 5A and 5B.

According to these embodiments, a dummy pattern 148 is formed using the process for forming the control gate electrode. Continuously, using the dummy pattern 148 and the mask pattern 155 as an etch mask, the first conductive pattern 125 is formed. Generally, the process for forming the control gate electrode is defined by a minimum design rule and the cost of the process is high. Meanwhile, the photolithographic process for forming the cell-opening mask is defined by a loose design rule, such that the required cost is low. As a result, the first conductive pattern 125 may be formed by one high-cost process (for forming a dummy pattern) and one low-cost process (for forming a mask pattern).

Meanwhile, the embodiments illustrated in FIGS. 3 through 5 have two high-cost processes for forming the first conductive pattern 125 to an identical line width. That is, the step of forming the mask pattern 150 of the previous embodiments is an additional high-cost process that is defined by a small design rule.

In the exemplary embodiments, the first conductive pattern 125 is formed using the dummy pattern 148 as an etch mask according to a self-aligned method. Therefore, various problems that occur in the process due to the photoresist pattern may be prevented.

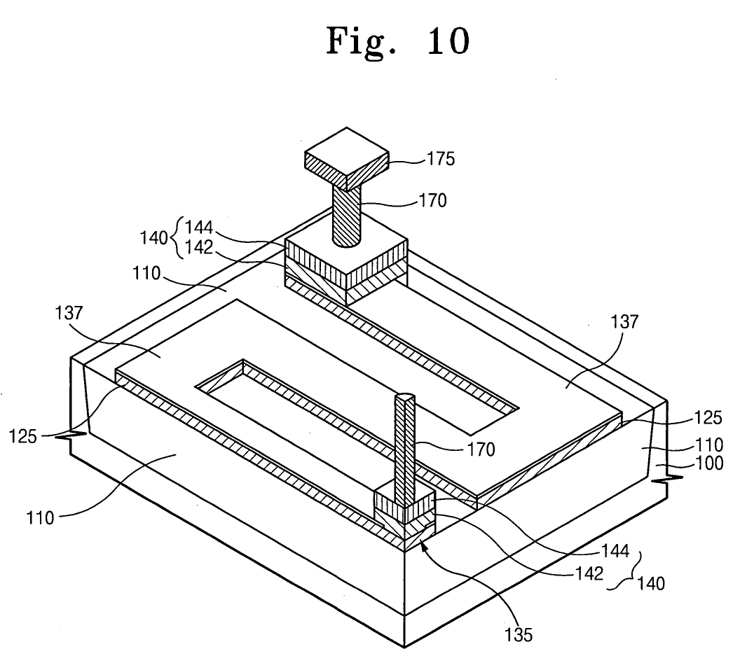

FIG. 10 is a perspective diagram illustrating a resistor of the semiconductor device in accordance with some embodiments of the invention.

Referring to FIG. 10, a field isolation layer 110 is disposed in a predetermined region of a semiconductor substrate 100 to define active regions. The field isolation layer 110 is formed using a trench technology and may be formed of silicon oxide.

A first conductive pattern 125 is disposed on the field isolation layer 110. The first conductive pattern 125 has a specific shape and may be a 100-400 Å thick polysilicon layer.

A gate interlayer insulating pattern 137 is disposed on the first conductive pattern 125. The gate interlayer insulating pattern 137 includes openings exposing both edges of the first conductive pattern 125. The gate interlayer insulating pattern 137 may have a sequential stack structure of silicon oxide-silicon nitride-silicon oxide (ONO).

Second conductive patterns 140 are formed on the both edges of the gate interlayer insulating pattern 137 to be directly in contact with the first conductive pattern 125 through the openings 135. That is, the gate interlayer insulating pattern 137 is interposed between the first conductive pattern 125 and the second conductive pattern 140 and the second conductive pattern 140 is disposed on the opening 135 exposing both edges of the first conductive pattern 125. The second conductive patterns 140 may be formed from a material selected from the group consisting of polysilicon, tungsten, cobalt, tungsten silicide, and cobalt silicide. According to these embodiments of the invention, the second conductive patterns 140 include a bottom second conductive pattern 142 and a top second conductive pattern 144. The bottom second conductive pattern 142 is a polysilicon layer and the top second conductive pattern 144 is a tungsten silicide layer.

An interlayer insulating layer (not shown) is disposed on the semiconductor substrate with the second conductive pattern 140. The interlayer insulating layer may be a silicon oxide layer.

Through the interlayer insulating layer, a plug 170 is disposed to be in contact with a top surface of the second conductive pattern 140. An interconnection 175 is disposed on the interlayer insulating layer to be in contact with the plug 170. Embodiments of the invention use the first conductive pattern 125 as a resistor, and the second conductive pattern 140, the plug 170, and the interconnections 175, which are disposed at both ends of the first conductive pattern, as terminals.

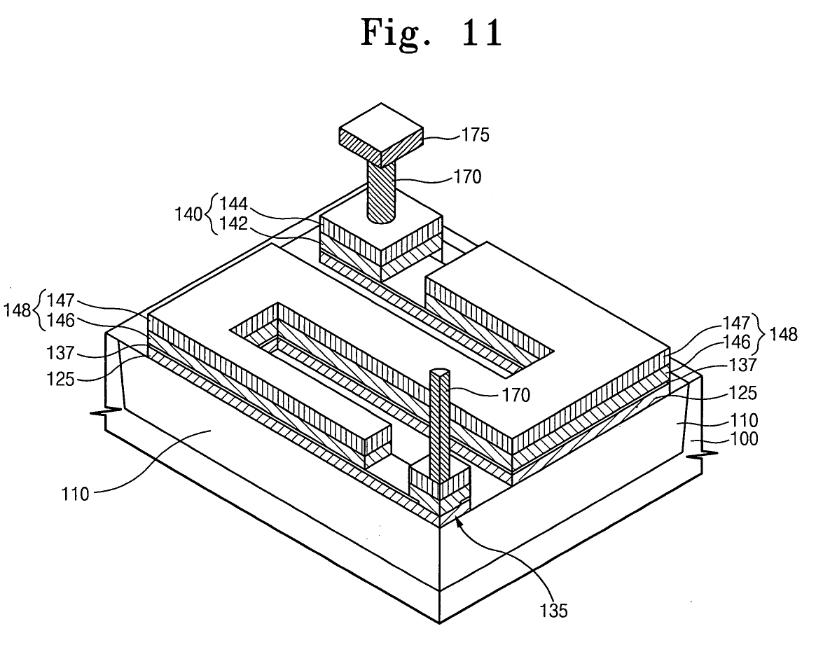

FIG. 11 is a perspective diagram illustrating a resistor of a semiconductor device according to some other embodiments of the invention. These embodiments share some similar characteristics with the embodiments illustrated in FIG. 10. Thus, a duplicative explanation will be omitted.

Referring to FIG. 11, a dummy pattern 148 is disposed on the gate interlayer insulating pattern 137, spaced apart from the second conductive patterns 140. The dummy pattern 148 comprises a bottom dummy pattern 146 and a top dummy pattern 147. The dummy pattern 148 is formed of the same material and has the same thickness as the second conductive pattern 140.

According to embodiments of the invention, the resistors may be formed using a process for fabricating a flash memory cell transistor. Therefore, with respect to the material type and thickness, the first conductive pattern 125 is the same as the floating gate electrode 184. Similarly, the bottom second conductive pattern 142, the dummy pattern 146, and the bottom control gate 188 are identical to one another. The top second conductive pattern 144, the top dummy pattern 147, and the top control gate 189 are the same.

According to some embodiments of the invention, a gate interlayer insulating layer is patterned to form openings exposing a first conductive layer. A second conductive pattern is formed to be in contact with the first conductive layer, and then plug interconnections used as two terminals of a resistor are formed to be in contact with the second conductive pattern. Therefore, a contact resistance between the plug interconnection and the second conductive pattern may be stabilized.

According to some embodiments of the invention, the first conductive layer is formed of polysilicon, such that the resistor may be short. Thus, the area of the resistor is reduced and semiconductor devices can be highly integrated.

Moreover, according to some embodiments of the invention, the resistor may be fabricated using the same process as forming a flash memory cell gate pattern. Therefore, good-qualified resistors can be fabricated without additional steps.

According to some other embodiments of the invention, a dummy pattern is formed during the same process that a second conductive pattern is formed. The dummy pattern is used as an etch mask for defining a first conductive pattern. Therefore, electrically sound resistors can be fabricated without additional cost.

There are many way to practice the invention. What follows are descriptions of example, non-limiting, embodiments of the invention.

According to some embodiments of the invention, a method for fabricating a semiconductor device includes forming a plug on second conductive patterns. The method includes sequentially forming first and second conductive layers and patterning the second conductive layer to form second conductive patterns disposed on the first conductive layer. The second conductive patterns are disposed on the first conductive layer. A mask pattern is formed on the semiconductor substrate with the second conductive patterns. Then, using the mask pattern and the second conductive patterns as an etching mask, the first conductive layer is etched to form a first conductive pattern electrically connecting the second conductive patterns. Plug interconnections are formed to be in contact with the second conductive patterns.

According to some embodiments of the invention, the first conductive layer is a polysilicon layer, and the second conductive layer is one selected from the group consisting of a polysilicon layer, a tungsten layer, a tungsten silicon layer, and a cobalt silicide layer. In addition, the first conductive layer may be formed 100-400 Å thick.

According to some embodiments of the invention, before forming the second conductive layer, a gate interlayer insulating layer is formed on the semiconductor substrate with the first conductive layer. The gate interlayer insulating layer is patterned to form at least two openings exposing a top of the first conductive layer. The second conductive patterns may be formed using an etch recipe having an etch selectivity with respect to the gate interlayer insulating layer. The second conductive patterns are formed on openings of the gate interlayer insulating layer to be in direct contact with a top surface of the first conductive pattern.

According to some other embodiments of the invention, a dummy pattern is also formed at the same time the second conductive patterns are formed. The dummy pattern is formed on the gate interlayer insulating layer and spaced apart from the second conductive patterns. In this case, the mask pattern is formed to cover the gate interlayer insulating layer between the second conductive patterns and the dummy pattern.

The mask pattern is formed on the first conductive layer to connect the second conductive patterns. Therefore, the mask pattern is used as an etch mask during the process of forming the first conductive pattern.

After forming the second conductive layer, a capping layer may be further formed on the second conductive layer. The capping layer is patterned to form a capping pattern disposed on the second conductive pattern. The capping pattern is formed together with the second conductive pattern, and it is used as an etch mask in the etch process for forming the first conductive pattern.

Before forming the plug interconnection, an interlayer insulating layer may be deposited on a surface of the semiconductor substrate and the first conductive pattern. Then, the interlayer insulating layer is patterned to form openings exposing top surfaces of the second conductive patterns. The plug interconnections are formed to fill the openings formed in the interlayer insulating layer.

Before forming the first conductive layer, a field isolation layer may be formed in a predetermined region of the semiconductor device. The first and second conductive patterns are disposed on the field isolation layer.

According to some other embodiments of the invention, a first conductive layer is formed on a semiconductor substrate. Then, there is formed a gate interlayer insulating layer including two openings exposing a top surface of the first conductive layer at a specific region. A second conductive layer is formed on the semiconductor substrate with the gate interlayer insulating layer. The second conductive layer is patterned until the gate interlayer insulating layer is exposed, thereby forming second conductive patterns disposed on the openings. A mask pattern is formed on the semiconductor substrate with the second conductive patterns to connect the second conductive patterns. Using the mask pattern and the second conductive pattern as an etch mask, the gate interlayer insulating layer and the first conductive pattern are patterned to a first conductive pattern and a gate interlayer insulating pattern that are sequentially stacked. Plug interconnections are formed connected to the second conductive patterns.

According to some other embodiments of the invention, a first conductive layer is formed on a semiconductor substrate and then there is formed a gate interlayer insulating layer including two openings exposing a top surface of the first conductive layer at a specific region. A second conductive layer is formed on the semiconductor substrate with the gate interlayer insulating layer. The second conductive layer is patterned until the gate interlayer insulating layer is exposed, thereby forming second conductive patterns disposed on the openings and a dummy pattern spaced apart from the second conductive patterns. Mask patterns are formed to cover the gate interlayer insulating layer exposed between the second conductive patterns and the dummy pattern. Then, using the mask patterns, the second conductive patterns and the dummy pattern as an etch mask, the gate interlayer insulating layer and the first conductive pattern are patterned. Thus, there are formed a first conductive pattern and a gate interlayer insulating pattern that are sequentially stacked. Plug interconnections are formed connected to the second conductive patterns.

According to some other embodiments of the invention, a semiconductor substrate including a cell array region and a resistor region is prepared. A flash memory cell gate pattern is formed in the cell array region, and a resistor pattern is formed in the resistor region. The resistor pattern is formed during the same process as forming the cell gate pattern of the flash memory cell gate pattern. The flash memory cell gate pattern includes a floating gate electrode, a cell gate interlayer insulating layer, and a control gate electrode that are sequentially stacked. In addition, the resistor pattern includes a first conductive pattern, a gate interlayer insulating pattern, and a second conductive pattern that are sequentially stacked.

The cell array region and the resistor region are defined by forming a field isolation layer in the semiconductor substrate. The resistance pattern is formed on the field isolation layer.

Forming the flash memory cell gate pattern and the resistance pattern includes forming a first conductive layer on the semiconductor substrate. A gate interlayer insulating layer is formed on a surface of the semiconductor substrate and the first conductive layer, and then the gate interlayer insulating layer is patterned to form openings exposing a top surface of the first conductive layer at a predetermined region. A second conductive layer is formed on the gate interlayer insulating layer to be in contact with the first conductive layer through the openings. The second conductive layer is patterned to form the control gate electrodes and the second conductive patterns at the cell array region and the resistor region, respectively. A mask pattern that exposes the cell array region is formed at the resistor region to cover the gate interlayer insulating layer between the second conductive patterns. Using the control gate electrodes, the second conductive patterns and the mask pattern as an etch mask, the gate interlayer insulating layer and the first conductive layer are etched. Therefore, the floating gate electrodes and the first conductive patterns are formed at the cell array region and the resistor region, respectively.

Preferably, patterning the gate interlayer insulating layer includes removing a gate interlayer insulating layer of a source selection line or a ground selection line disposed at the cell array region.

According to some other embodiments of the invention, there is provided a semiconductor device including plug interconnections formed on second conductive patterns. The device includes a first conductive pattern disposed on a predetermined region of a semiconductor substrate, second conductive patterns disposed on both edges of the second conductive pattern, respectively, and plug interconnections connected to top surfaces of the second conductive patterns. The second conductive patterns are in direct contact with the second conductive patterns.

The first conductive pattern is a 100-400 Å thick polysilicon layer, and the second conductive pattern is formed of at least one material selected from the group consisting of polysilicon, tungsten, tungsten silicide, and cobalt silicide.

According to an exemplary embodiment of the invention, a gate interlayer insulating pattern is disposed between the first and second conductive patterns. The gate interlayer insulating pattern includes an opening connecting the first and second conductive patterns.

According to another embodiment of the invention, a dummy pattern is further disposed on the gate interlayer insulating layer and spaced apart from the second conductive pattern. The dummy patterned is disposed vertically on the first conductive pattern.

Preferably, a field isolation layer is also formed in a predetermined region of the semiconductor substrate to define active regions. The first and second conductive patterns and the plug interconnections are disposed on the field isolation layer.

According to some embodiments of the invention, a semiconductor device includes a semiconductor substrate having a cell array region and a resistor region, a flash memory cell gate pattern disposed on the cell array region, and a resistor pattern disposed on the resistor region. The cell gate pattern includes a floating gate electrode, a cell gate interlayer insulating layer, and a control gate electrode, and the resistor pattern includes a first conductive pattern, a gate interlayer insulating pattern, and a second conductive pattern that are sequentially stacked. The first conductive pattern, the gate interlayer insulating pattern, and the second conductive pattern are formed of the same materials and have the same thickness as the floating gate electrode, the cell gate interlayer insulating layer, and the control gate electrode, respectively.

A dummy pattern may also be disposed on the gate interlayer insulating pattern at the resistor region and spaced apart from the second conductive pattern. The dummy pattern is formed of the same material and has the same thickness as the control gate electrode.

While the invention has been particularly shown and described with reference to exemplary embodiments thereof, it will be understood by those skilled in the art that the foregoing and other changes in form and details may be made therein without departing from the spirit and scope of the invention as defined in the following claims.

We claim:

1. A method of fabricating a resistor in a semiconductor device comprising:
sequentially forming a first conductive layer and a second conductive layer on a semiconductor substrate;
patterning the second conductive layer to form two second conductive patterns disposed on the first conductive layer;
forming a mask pattern on the semiconductor substrate and the two second conductive patterns, the mask pattern covering a predetermined region of the first conductive layer;
patterning the first conductive layer using the mask pattern and the two second conductive patterns as an etch mask to form a first conductive pattern for electrically connecting the two second conductive patterns; and
forming plug interconnections connected to the two second conductive patterns.

2. The method of claim 1, wherein sequentially forming a first conductive layer and a second conductive layer comprises:
sequentially forming a polysilicon layer and a layer selected from the group consisting of a polysilicon layer, a tungsten layer, a tungsten silicide layer, and a cobalt silicide layer.

3. The method of claim 1, wherein forming a first conductive layer comprises:
forming the first conductive layer to a thickness of 100 to 400 Å.

4. The method of claim 1, further comprising, before forming the second conductive layer:
forming a gate interlayer insulating layer on the first conductive layer; and
patterning the gate interlayer insulating layer to form two openings exposing a top of the first conductive pattern.

5. The method of claim 4, wherein patterning the second conductive layer comprises:
patterning the second conductive layer with an etch recipe having an etch selectivity with respect to the gate interlayer insulating layer.

6. The method of claim 4, wherein the two second conductive patterns are formed on the two openings of the gate interlayer insulating layer to be directly in contact with the top of the first conductive pattern.

7. The method of claim 1, wherein the mask pattern is used as an etch mask in an etch process for forming the first conductive pattern by connecting the second conductive patterns on the first conductive layer.

8. The method of claim 4, wherein patterning the second conductive layer to form two second conductive patterns comprises:
forming a dummy pattern on the gate interlayer insulating layer, the dummy pattern separated from the two second conductive patterns.

9. The method of claim 8, wherein the mask pattern is formed to cover the gate interlayer insulating layer between one of the two second conductive patterns and the dummy pattern.

10. The method of claim 1, further comprising, after forming the second conductive layer:
forming a capping layer on the second conductive layer; and
patterning the capping layer to form a capping pattern disposed on the second conductive layer, wherein the capping pattern is formed during the process of forming the two second conductive patterns and is used as an etch mask in the etch process for forming the first conductive pattern.

11. The method of claim 1, further comprising, before forming the plug interconnections:
depositing an interlayer insulating layer on a surface of the semiconductor substrate and the first conductive pattern; and
patterning the interlayer insulating layer to form openings that expose top surfaces of the two second conductive patterns, wherein the plug interconnections are formed to fill the openings.

12. The method of claim 1, further comprising, before forming the first conductive layer:
forming a field isolation layer in a predetermined region of the semiconductor substrate, wherein the first and the two second conductive patterns are disposed on the field isolation layer.

13. A method for fabricating a resistor comprising:
forming a first conductive layer on a semiconductor substrate;
forming a gate interlayer insulating layer that has two openings exposing predetermined regions of a top surface of the first conductive layer;
forming a second conductive layer on the semiconductor substrate and the gate interlayer insulating layer;
patterning the second conductive layer until the gate interlayer insulating layer is exposed, thereby forming second conductive patterns disposed on the two openings;
forming a mask pattern that connects the second conductive patterns;
patterning the gate interlayer insulating layer and the first conductive layer using the mask pattern and the second conductive patterns as an etch mask, thereby forming a first conductive pattern and a gate interlayer insulating pattern that are sequentially stacked; and
forming plug interconnections connected to the second conductive patterns.

14. The method of claim 13, wherein patterning the second conductive layer comprises:
patterning with an etch recipe having an etch selectivity with respect to the gate interlayer insulating layer.

15. The method of claim 13, wherein forming plug interconnections comprises:
depositing an interlayer insulating layer on a surface of the semiconductor substrate and the first conductive pattern;
patterning the interlayer insulating layer to form openings that expose a top surface of the second conductive patterns; and
filling the openings with the plug interconnections.

16. The method of claim 13, further comprising, before forming the first conductive layer:
forming a field isolation layer in a predetermined region of the semiconductor substrate, wherein the first and second conductive patterns are disposed on the field isolation layer.

17. A method for fabricating a resistor comprising:
forming a first conductive layer on a semiconductor substrate;
forming a gate interlayer insulating layer that includes two openings that expose predetermined regions of a top surface of the first conductive layer;
forming a second conductive layer on the semiconductor substrate and the gate interlayer insulating layer;
patterning the second conductive layer until the gate interlayer insulating layer is exposed, thereby forming second conductive patterns disposed on the two openings and a dummy pattern spaced apart from the second conductive patterns;
forming mask patterns covering the gate interlayer insulating layer that is exposed between the second conductive patterns and the dummy pattern;
using the mask patterns, the second conductive patterns, and the dummy pattern as an etch mask, patterning the gate interlayer insulating layer and the first conductive layer, thereby forming a gate interlayer insulating pattern and a first conductive pattern, respectively, that are sequentially stacked; and
forming plug interconnections connected to the second conductive patterns.

18. The method of claim 17, wherein patterning the second conductive layer comprises:
patterning with an etch recipe having an etch selectivity with respect to the gate interlayer insulating layer.

19. The method of claim 17, wherein forming the plug interconnections comprises:
depositing an interlayer insulating layer on a surface of the semiconductor substrate and the first conductive pattern;
patterning the interlayer insulating layer to form openings that expose top surfaces of the second conductive patterns; and
filling the openings with the plug interconnections.

20. The method of claim 17, further comprising, before forming the first conductive layer:
forming a field isolation layer in a predetermined region of the semiconductor substrate, wherein the first and second conductive patterns are disposed on the field isolation layer.

21. A resistor comprising:
a first conductive pattern disposed on a predetermined region of a semiconductor substrate;
second conductive patterns that are disposed on edges of the first conductive pattern and are directly in contact with the first conductive pattern; and
plug interconnections connected to top surfaces of the second conductive patterns.

22. The resistor of claim 21, wherein the first conductive pattern is a 100 Å to 400 Å thick layer of polysilicon.

23. The resistor of claim 21, wherein the second conductive pattern is formed of at least one material selected from the group consisting of polysilicon, tungsten, tungsten silicide, and cobalt silicide.

24. The resistor of claim 21, further comprising:
a gate interlayer insulating pattern disposed between the first and second conductive patterns, wherein the gate interlayer insulating pattern includes openings where the first conductive pattern contacts the second conductive patterns.

25. The resistor of claim 24, further comprising:
a dummy pattern disposed on the gate interlayer insulating layer, wherein the dummy pattern is spaced apart from the second conductive patterns and is disposed vertically on the first conductive pattern.

26. The resistor of claim 21, further comprising:
a field isolation layer formed in a predetermined region of the semiconductor substrate to define active regions, wherein the first and second conductive patterns and the plug interconnections are disposed on the field isolation layer.

27. A semiconductor device comprising:
a semiconductor substrate including a cell array region and a resistor region;
a flash memory cell gate pattern disposed at the cell array region, the flash memory cell gate pattern including a floating gate electrode, a cell gate interlayer insulating layer, and a control gate electrode that are sequentially stacked; and
a resistor pattern disposed at the resistor region, the resistor pattern including a first conductive pattern, a gate interlayer insulating pattern, and a second conductive pattern that are sequentially stacked,
wherein the first conductive pattern, the gate interlayer insulating pattern, and the second conductive pattern are formed of the same materials and have the same thickness as the floating gate electrode, the cell gate interlayer insulating layer, and the control gate electrode, respectively.

28. The device of claim 27, further comprising:
a dummy pattern disposed on the gate interlayer insulating pattern at the resistor region, wherein the dummy pattern is spaced apart from the second conductive pattern, and the dummy pattern is formed of the same material and has the same thickness as the control gate electrode.

29. A method for fabricating a semiconductor device, comprising:
preparing a semiconductor substrate including a cell array region and a resistor region;
forming a flash memory cell gate pattern including a floating gate electrode, a cell gate interlayer insulating layer, and a control gate electrode that are sequentially stacked at the cell array region; and
forming a resistor pattern including a first conductive pattern, a gate interlayer insulating pattern, and a second conductive pattern that are sequentially stacked at the resistor region, wherein the resistor pattern and the flash memory cell gate pattern are simultaneously formed during the same process.

30. The method of claim 29, wherein preparing a semiconductor substrate comprises:
forming a field isolation layer defining the active region in the semiconductor substrate, wherein the resistor pattern is formed on the field isolation layer.

31. The method of claim 29, wherein forming the flash memory cell gate pattern and the resistor pattern comprises:
forming a first conductive layer on the semiconductor substrate;
forming a gate interlayer insulating layer on a surface of the semiconductor substrate and the first conductive layer;
patterning the gate interlayer insulating layer to form openings exposing predetermined regions of a top surface of the first conductive layer;
forming a second conductive layer on the gate interlayer insulating layer, the second conductive layer in contact with the first conductive layer through the openings;
patterning the second conductive layer to form the control gate electrodes at the cell array region and the second conductive patterns at the resistor region;
forming a mask pattern at the resistor region to cover the gate interlayer insulating layer between the second conductive patterns and to expose the cell array region; and
using the control gate electrodes, the second conductive patterns, and the mask pattern as an etch mask, etching the gate interlayer insulating layer and the first conductive layer to form the floating gate electrodes at the cell array region and the first conductive patterns at the resistor region, respectively.

32. The method of claim 31, wherein patterning of the gate interlayer insulating layer comprises:
removing the gate interlayer insulating layer from a selection line disposed at the cell array region, the selection line chosen from the group consisting of a source selection line and a ground selection line.
